(19) United States
(12) Patent Application Publication
(10) Pub. No.: US 2002/0168809 A1
(43) Pub. Date: Nov. 14, 2002

(54) Semiconductor circuits and devices on germanium substrates

(76) Inventors: Karim S. Boutros, Moorpark, CA (US); Nasser H. Karam, Northridge, CA (US); Dimitri Krut, Encino, CA (US); Moran Haddad, Winnetka, CA (US)

Correspondence Address: Steven W. Hays, Artz & Artz, P.C., Suite 250, 28333 Telegraph Road, Southfield, MI, 48034, US

(21) Appl. No.: 09/850,773

(22) Filed: May 8, 2001

(51) Int. Cl. H01L 29/06; H01L 31/0328

(52) U.S. Cl. 438/169; 257/19; 257/21; 257/13; 257/552; 438/192; 438/172; 438/519

(57) ABSTRACT

A semiconductor device having at least one layer of a group III-V semiconductor material epitaxially deposited on a group III-V nucleation layer adjacent to a germanium substrate. By introducing electrical contacts on one or more layers of the semiconductor device, various optoelectronic and microelectronic circuits may be formed on the semiconductor device having similar quality to conventional group III-V substrates at a substantial cost savings. Alternatively, an active germanium device layer having electrical contacts may be introduced to a portion of the germanium substrate to form an optoelectronic integrated circuit or a dual optoelectronic and microelectronic device on a germanium substrate depending on whether the electrical contacts are coupled with electrical contacts on the germanium substrate and epitaxial layers, thereby increase the functionality of the semiconductor devices.

### TECHNICAL FIELD

The present invention generally relates to semiconductor devices and, more particularly, semiconductor circuits and devices on germanium substrates.

### BACKGROUND ART

It is known to use germanium as a substrate material for growth in III-V materials. Devices that use these III-V materials are typically photonic devices such as solar cells or light emitting diodes (“LEDs”). To produce such devices, intrinsic, or conventional, substrates were used for growth of these devices, where very high quality epitaxial films, as well as lattice matching are required to achieve good device performance. The existence of intrinsic substrates in the “semi-insulating” form enabled high-frequency operation of these microelectronic and optoelectronic devices. The disadvantage of these intrinsic substrates is their high cost of use and manufacture.

Germanium photonic devices have also been combined with III-V devices to produce multifunction semiconductor devices. In this respect, the optical properties of Germanium have been combined with the optical properties of III-V materials to efficiently convert solar energy into electricity. To date, it is believed that this technology has been limited to photovoltaic applications.

One problem with currently available technology is the cost of using a conventional substrate such as GaAs and InP in microelectronic devices. This cost has effectively prevented III-V devices from being used in many different markets and applications.

Another problem with currently available technology is that growth substrates have typically been limited to III-V materials for use as templates to ensure high quality of the epitaxial III-V films.

It would be highly desired to combine the material and electrical properties of germanium, which is a group IV semiconductor, with material and electrical properties of III-V compounds in such a way as to create a cheaper and functionally different optoelectronic and microelectronic devices and/or a combination thereof as compared to the presently available technology.

### SUMMARY OF THE INVENTION

It is thus an object of the present invention to create a less expensive and functionally different optoelectronic and microelectronic devices and/or a combination thereof as compared to the presently available technology.

The above object is accomplished forming a semiconductor device having at least one layer of a group III-V semiconductor material epitaxially deposited on a germanium substrate. Electrical contacts are formed and coupled on the germanium substrate layer and at least one layer of the group III-V semiconductor material to form the optoelectronic or microelectronic device.

In an alternative arrangement, a portion of the germanium substrate layer is doped to form an active germanium device layer. An electrical contact is formed on this active germanium device layer. This electrical contact is coupled to the electrical contacts on the germanium substrate layer and at least one layer of the group III-V semiconductor material to form the optoelectronic integrated circuit. Alternatively, where this electrical contact is not coupled to the electrical contacts on the germanium substrate layer and at least one layer of the group III-V semiconductor material, a device having a separate microelectronic transistor and optoelectronic device formed on a single germanium substrate may be achieved.

Other objects and advantages of the present invention will become apparent upon the following detailed description and appended claims, and upon reference to the accompanying drawings.

### BRIEF DESCRIPTION OF THE DRAWINGS

FIG. 1 depicts a semicircuit device according to one preferred embodiment of the present invention;

FIG. 2 depicts an optoelectronic integrated circuit according to another preferred embodiment of the present invention;

FIG. 3 depicts a specific embodiment of FIG. 1;

FIG. 4a is an I-V plot of transistor device of FIG. 3 when it is wired in a common-emitter configuration at four distinct base current levels; and

FIG. 4b is a gummel plot of collector current and base current versus the applied collector-emitter and base-emitter voltages, respectively, of the device of FIG. 3.

### BEST MODES FOR CARRYING OUT THE INVENTION

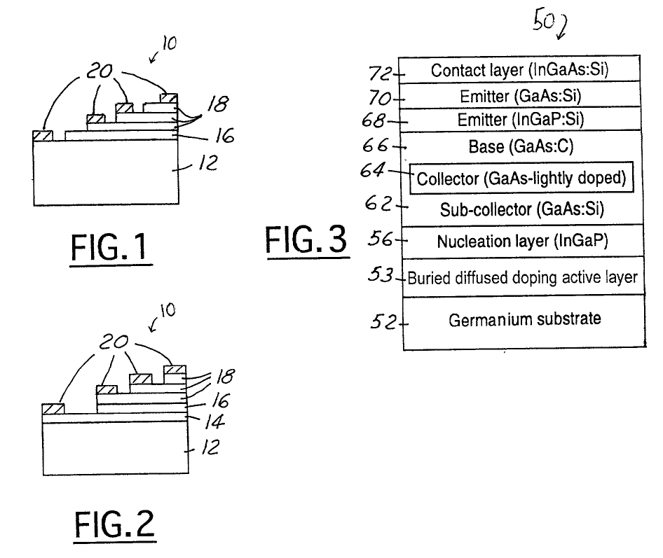

FIGS. 1 and 2 show schematic representations of forming a semiconductor device 1 0 that is used to form an optoelectronic integrated circuit that is the heart of the present invention.

Referring now to FIG. 1, a schematic representation of a semiconductor device 10, according to one preferred embodiment is depicted as consisting of a germanium substrate 12, a nucleation layer 16, a series of III-V epitaxial layers 18, and a plurality of electrical contacts 20. In an alternative preferred embodiment, as shown in FIG. 2, a buried germanium diffused-doping active layer 14, is formed on a top portion of the germanium substrate 12 adjacent to the nucleation layer 16.

Preferably, the III-V semiconductor compounds used in the epitaxial layers 18 of the optoelectronic circuits are (Al, In, Ga) arsenide compounds and/or (Al, In, Ga) phosphide compounds which are grown on germanium substrates 12.

To form the device 10, the germanium substrate 12 is loaded in a metal-organic vapor phase epitaxy (“MOVPE”) reaction chamber, where it is subjected to epitaxial layer deposition using convention MOVPE techniques. Alternatively, molecular beam epitaxy (“MBE”) may be used to deposit the epitaxial layers. During the step the nucleation layer 16 is deposited. Preferably, the nucleation layer is an InGaP layer that is lattice-matched to the germanium substrate 12. The nucleation layer serves dual functions in this invention. First, the nucleation layer 16 enables the growth of high quality epitaxial layers of III-V materials to form the III-V structures as proposed here. Second, the nucleation layer 16 serves as a diffusion barrier to allow control of dopant diffusion in the germanium substrate 12 to form the buried germanium diffused-doping active layer 14.

By flowing the appropriate gases during the MOVPE growth run, doping materials are diffused into the germanium substrate 12 to form the germanium diffused-doping active layer 14. For example, an n-type dopant can be diffused in a p-type germanium substrate to form a p-n junction photodetector device. The doping profile and the number of diffused layers is part of the device 10 structure design and is controlled by the thickness and conductivity type of the III-V nucleation layer 16 and the dopant flux and flux sequence used during the MOVPE growth run.

On top of the nucleation layer 16, III-V semiconductor layers 18 are epitaxially deposited successively to form the desired device structure. The number and type of epitaxial layers 18 may vary depending upon the application. For example, a heterojunction bipolar transistor structure may have an n-p-n GaAs/GaAs/InGaP epitaxial layer structure.

After the completion of the III-V epitaxial layers 18, the resultant structure, or wafer, is subjected to an etching process using conventional photolithography techniques to expose the germanium active device layer 14 from underneath the III-V epitaxial layers 18.

Next, using conventional photolithography and semiconductor fabrication techniques, electrical contacts 20 are then formed to the various layers of the semiconductor device 10. While contacts 20 may be formed on any layers, they are preferably formed on one or more of the III-V epitaxial layers 18, the doped germanium active layer 14, and on the back side of the germanium substrate layer 12. Depending upon which layers the electrical contacts 20 in FIGS. 1 and 2 are coupled to, and which electrical contacts 20 are coupled, various preferred embodiments of microelectronic, optoelectronic, and optoelectronic integrated circuits (“OEIC”) may be formed. These are described below.

For example, by coupling together some of the electrical contacts 20 of the III-V epitaxial layers 18 which are not intended for photosensitivity, various microelectronic transistors may be produced. Similarly, by coupling together some of the electrical contacts 20 of the light sensitive growth layers, such as the germanium substrate 12, either with or without the non-light sensitive growth layers, optoelectronic, or optically-active devices, may be produced. Some examples of optoelectronic devices include the formation of an active germanium-device 14 such as a photodetector, light emitting diode (“LED”), or laser. The use of germanium substrates 12 as a template for these microelectronic and/or optoelectronic devices offers a substantial cost advantage in terms of manufacturing while maintaining the high quality of the III/V epitaxial as compared with traditional substrates such as GaAs and InP.

Further, the combination of two or more device structures described above, also known as monolithic integration, could result in a single device having a microelectronic transistor circuit and an optoelectronic device.

By combining the electrical contacts 20 of the germanium substrate 12 and the epitaxial layers 18, an optoelectronic or microelectronic device can be formed with high performance and cost effectiveness not previously attainable in either microelectronic or optoelectronic devices using a conventional substrate. By combining electrical contacts 20 of the germanium substrate 12 with the germanium substrate active layer 14 and epitaxial layers 18, an OEIC can be formed with functionality and high performance not previously attainable in either microelectronic or optoelectronic devices.

The germanium substrate 12 is a key aspect of the invention, as it provides certain optical and electrical properties that are unique and different from III-V semiconductors, such as the bandgap of a semiconductor and electrical mobilities of electrons and holes. These elements and properties of the germanium substrate 12 will enable circuit functionality, such as sensitivity to particular wavelengths for a photodetector, which when combined with circuit functionality of III-V devices will enable performance not possible with the present art using III-V devices exclusively. The substrate doping and type (n or p conductivity type) is an important parameter in the choice of the germanium substrate 12 to achieve the desired device structure. Low level of doping would be preferred to enable high frequency operation of the microelectronic circuit.

In an alternative embodiment (not shown), this buried germanium diffused-doping active layer 14 can be further patterned, where selected regions will be masked form further diffusion to occur, and additional diffusion is performed again to form additional junctions in the germanium substrate. In this way, spatial differences in the diffused profile of dopants can exist simultaneously in the same wafer.

Referring now to FIG. 3, an OEIC device 50 according to one preferred embodiment of the present invention is depicted. To form the OEIC device 50, an n-type as well as a p-type germanium substrate 52 were loaded simultaneously in a metal-organic vapor phase epitaxy (“MOVPE”) reaction chamber, where it is subjected to epitaxial layer deposition using conventional MOVPE techniques. The substrate 52 was chosen to be six degrees off the normal crystallographic cut, which insures the optimum quality of the III-V crystals deposited on it. During the step the InGaP nucleation layer 56 is deposited.

By flowing the appropriate gases during the MOVPE growth run, doping materials are diffused through the nucleation layer 56 and a portion of the germanium substrate 52 to form a buried germanium diffused-doping active layer 53. For example, as depicted in FIG. 3, an n-type dopant is diffused into a p-type germanium substrate 52 to form a p-n junction photodetector device. The doping profile and the number of diffused layers is part of the device structure design and is controlled by the thickness of the InGaP nucleation layer 56 and the dopant flux and flux sequence used during the MOVPE growth run.

On top of the nucleation layer 56, III-V semiconductor layers are epitaxially deposited successively to form a typical InGaP/GaAs heterojunction bipolar transistor (“HBT”) structure 60. Here, these layers are a GaAs:Si subcollector layer 62, a lightly-doped GaAs collector layer 64, a GaAs:C base layer 66, a InGaP:Si emitter layer 68, a GaAs:Si emitter layer 70, and a InGaAs:Si contact layer 72. Following the growth sequence, the layers 62, 64, 66, 68, 70, 72 are fabricated into devices with large area to extract direct current performance of the HBTs.

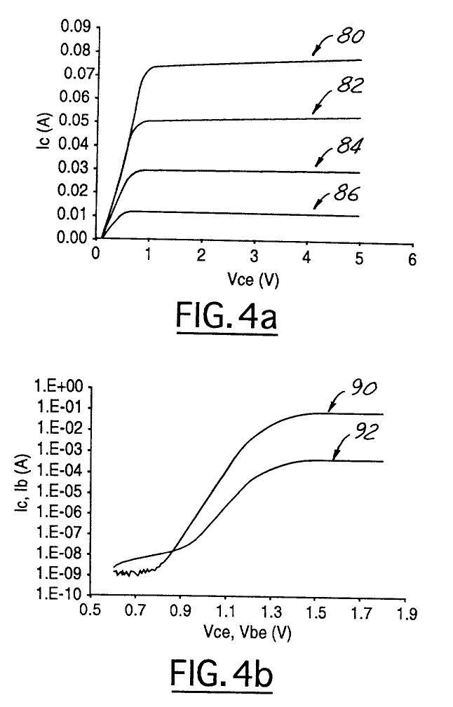

FIGS. 4a and 4b depict the electrical curves describing the performance of an HBT as in FIG. 3. FIG. 4a is an I-V plot of collector current (“Ic”) versus common-emitter voltage (“Vce”) and FIG. 4b is a gummel plot of Ic and base current (“Ib”) versus Vce and base-emitter voltage (“Vbe”), respectively. Each is described below.

FIG. 4a shows the electrical characteristics of a transistor device as depicted in FIG. 3 when it is wired in a common-emitter configuration. Each curve shows the behavior of Ic as a function of the Vce at a particular Ib. For example, plot 80 depicts the behavior of Ic for an Ib of 400 microamps, plot 82 depicts the behavior of Ic for an Ib of 300 microamps plot 84 depicts the behavior of Ic for an Ib of 200 microamps and plot 86 depicts the behavior of Ic for an Ib of 100 microamps. Ones skilled in the art would recognize that the curves depicted in plots 80, 82, 84 and 86 in FIG. 4a show that the device of FIG. 3 behaves as a typical transistor.

FIG. 4b shows a gummel plot of the behavior of Ic versus Vce, shown as plot 90, and Ib versus Vbe, shown as plot 92 of the device of FIG. 3. In this wiring configuration, the base and collector contacts are wired together. Ones skilled in the art would recognize that FIG. 4b depicts a transistor device showing good performance, indicating a current gain for currents as low as 10 nanoamps.

When compared to equivalent conventional III-V HBT structures deposited on conventional III-V substrates, FIGS. 4a and 4b illustrate graphically that the OEIC device 50 of FIG. 3 showed equivalent performance. This indicates that the use of germanium substrates 52 has resulted in the same high performance as conventional III-V HBT structures.

The numerous advantages of the present invention are centered on the realization of an OEIC combining the properties of germanium as a substrate and as part of an active device, with known advantages of III-V microelectronic/optoelectronic components in high performance circuits.

First, the use of germanium as a substrate for microelectronic integrated circuits offers a significant cost reduction, in the range of two to ten times cheaper, compared to conventional substrates such as GaAs and InP substrates. Second, the current method for growth of III-V semiconductor layers on germanium substrates produces microelectronic and optoelectronic devices of comparable quality to currently available conventional substrates. Thus, the present invention offers significant cost reduction without a corresponding drop in quality.

Third, by introducing an active germanium device 14 to the germanium substrate 12, an optoelectronic circuit 10 can take advantage not only of the functional properties realized by the III-V circuit, but also of the properties of germanium as a different and distinct material from its III-V substrate counterparts. This advantage is particularly applicable when the germanium active device 14 is a photodetector, which would operate at different wavelengths, not achievable by the III-V semiconductor layers 18 grown on the germanium substrate 12. This enables light detection of signals that would otherwise be difficult to detect effectively if only III-V compound materials were used in the active circuit components.

While the invention has been described in terms of preferred embodiments, it will be understood, of course, that the invention is not limited thereto since modifications may be made by those skilled in the art, particularly in light of the foregoing teachings.

What is claimed is:

1. A semiconductor device comprising:
a germanium substrate having a first dopant;
a nucleation layer of group III-V materials adjacent to and disposed upon said germanium substrate;
at least one layer of a group III-V semiconductor material adjacent to and disposed upon said nucleation layer;
a first electrical contact formed on said germanium substrate; and
a second electrical contact formed on at least one of said at least one layer of a group III-V semiconductor material, wherein said second electrical contact is coupled with said first electrical contact.

2. The semiconductor device of claim 1, wherein a portion of said germanium substrate is doped with a second dopant to form an active germanium device layer.

3. The semiconductor device of claim 2, wherein a third electrical contact is formed on said active germanium device layer, said third electrical contact coupled with said first electrical contact and said second electrical contact.

4. The semiconductor device of claim 2, wherein a third electrical contact is formed on said active germanium device layer, wherein said third electrical contact is not coupled with said first electrical contact and said second electrical contact.

5. The semiconductor device of claim 1, wherein said first dopant is selected from the group consisting of an n-type conductivity dopant and a p-type conductivity dopant.

6. The semiconductor device of claim 2, wherein said second dopant is selected from the group consisting of an n-type conductivity dopant and a p-type conductivity dopant.

7. The semiconductor device of claim 1, wherein the level of said first dopant is a function of a desired frequency operating range for the semicircuit device.

8. The semiconductor device of claim 1, wherein said nucleation layer is lattice-matched to said germanium substrate.

9. The semiconductor device of claim 8, wherein said nucleation layer is an InGaP layer.

10. The semiconductor device of claim 1, wherein at least one layer of said at least one layer of a group III-V semiconductor material is selected from the group consisting of a contact layer, an emitter layer, a base layer, a collection layer, and a sub-collection layer.

11. A method for forming a semiconductor device comprising the steps of:
(a) providing a germanium substrate having a first dopant;
(b) epitaxially depositing a nucleation layer of a group III-V semiconductor material adjacent to and disposed upon said germanium substrate, wherein said nucleation layer is lattice-matched to said germanium substrate;
(c) epitaxially depositing at least one layer of a group III-V semiconductor material adjacent to and disposed upon said nucleation layer;
(d) forming a first electrical contact on said germanium substrate;
(e) forming a second electrical contact on at least one of said at least one layer of a group III-V semiconductor material; and
(f) coupling said first electrical contact with said second electrical contact.

12. The method of claim 11 further comprising the steps of:
(g) doping a portion of said germanium substrate prior to step (c) with a second dopant to form an active germanium device layer.

13. The method of claim 12 further comprising the steps of:
(h) forming a third electrical contact on said active germanium device layer; and
(i) coupling said first electrical contact with said second electrical contact and said third electrical contact.

14. The method of claim 13 further comprising the steps of:
(j) masking a portion of said germanium substrate after step (g) and prior to step (c);
(k) doping a second portion of said germanium substrate after step (j) and prior to step (c) with a third dopant to form a second active germanium device layer;
(l) forming a fourth electrical contact on said second active germanium device layer; and
(m) coupling said first electrical contact with said second electrical contact and said third electrical contact and said fourth electrical contact.

15. The method of claim 11, wherein the step of (b) epitaxially depositing a nucleation layer of a group III-V semiconductor material adjacent to and disposed upon said germanium substrate comprises the step of (b) epitaxially depositing a nucleation layer of a group III-V semiconductor material adjacent to and disposed upon said germanium substrate, wherein said nucleation layer is lattice matched to said germanium substrate.

16. The method of claim 15, wherein the step of (b) epitaxially depositing a nucleation layer of a group III-V semiconductor material adjacent to and disposed upon said germanium substrate, wherein said nucleation layer is lattice matched to said germanium substrate comprises the step of epitaxially depositing a nucleation layer of lattice-matched InGaP adjacent to and disposed upon said germanium substrate.

17. The method of claim 11, wherein the step of (b) epitaxially depositing a nucleation layer of a group III-V semiconductor material adjacent to and disposed upon said germanium substrate comprises the step of (b) epitaxially depositing a nucleation layer of a group III-V semiconductor material adjacent to and disposed upon said germanium substrate using metal-phase vapor phase epitaxy.

18. The method of claim 11, wherein the step of (b) epitaxially depositing a nucleation layer of a group III-V semiconductor material adjacent to and disposed upon said germanium substrate comprises the step of (b) epitaxially depositing a nucleation layer of a group III-V semiconductor material adjacent to and disposed upon said germanium substrate using molecular beam epitaxy.

19. The method of claim 11, wherein the step of (c) epitaxially depositing at least one layer of a group III-V semiconductor material adjacent to and disposed upon said nucleation layer comprises the step of (c) epitaxially depositing at least one layer of a group III-V semiconductor material having a first composition adjacent to and disposed upon said nucleation layer, wherein said first composition is a function of the thickness of said nucleation layer.

20. The method of claim 11, wherein the step of (c) epitaxially depositing at least one layer of a group III-V semiconductor material adjacent to and disposed upon said nucleation layer comprises the step of (c) epitaxially depositing at least one layer of a group III-V semiconductor material having a first composition adjacent to and disposed upon said nucleation layer, wherein said first composition is a function of the composition of said nucleation layer.

21. The method of claim 11, wherein the step of (c) epitaxially depositing at least one layer of a group III-V semiconductor material adjacent to and disposed upon nucleation layer comprises the step of (c) epitaxially depositing at least one layer of a group III-V semiconductor material having a first composition adjacent to and disposed upon said nucleation layer, wherein said first composition is a function of the composition and thickness of said nucleation layer.

22. A method for forming a semiconductor device comprising the steps of:
(a) providing a germanium substrate having a first dopant;
(b) epitaxially depositing a nucleation layer of a group III-V semiconductor material adjacent to and disposed upon said germanium substrate;
(c) doping a portion of said germanium substrate with a second dopant to form an active germanium device layer;
(d) epitaxially depositing at least one layer of a group III-V semiconductor material adjacent to and disposed upon said nucleation layer;
(e) forming a first electrical contact on said germanium substrate;
(f) forming a second electrical contact on said active germanium device layer;
(g) forming a third electrical contact on at least one of said at least one layer of a group III-V semiconductor material; and
(h) coupling said first electrical contact with said third electrical contact.

23. The method of claim 22, wherein the step of (b) epitaxially depositing a nucleation layer of a group III-V semiconductor material adjacent to and disposed upon said germanium substrate comprises the step of (b) epitaxially depositing a nucleation layer of a InGaP adjacent to and disposed upon said germanium substrate.

24. The method of claim 23, wherein the step of (b) epitaxially depositing a nucleation layer of a InGaP adjacent to and disposed upon said germanium substrate comprises the step of (b) epitaxially depositing a nucleation layer of a InGaP adjacent to and disposed upon said germanium substrate, wherein said InGaP is lattice matched to said germanium substrate.

25. The method of claim 22, wherein the step of (h) coupling said first electrical contact with said third electrical contact comprises the step of (h) coupling said first electrical contact with said second electrical contact and said third electrical contact.

26. The method of claim 22, wherein the step of (c) doping a portion of said germanium substrate with a second dopant to form an active germanium device layer comprises the step of (c) doping a portion of said germanium substrate with a second dopant to form a photodetector layer.
